(19) United States
(12) Patent Application Publication
(10) Pub. No.: US 2026/0287667 A1
(43) Pub. Date: Sep. 24, 2026

(54) MANAGING OPERATING PARAMETERS FOR IMPROVED STATE OF HEALTH OF A BATTERY ENERGY STORAGE SYSTEM

(71) Applicant: Inventus Holdings, LLC, Juno Beach, FL (US)

(72) Inventor: Joseph M. Arthur, II, Royal Palm Beach, FL (US)

(21) Appl. No.: 19/086,878

(22) Filed: Mar. 21, 2025

(51) Int. Cl. G01R 31/392; G01R 31/396

(52) U.S. Cl. CPC G01R 31/392; G01R 31/396

(57) ABSTRACT

A method is provided to optimize the state of health (SoH) of a battery energy storage system (BESS). The method involves determining the required electric power to meet a contractual obligation and dividing the batteries into multiple subsets. Each subset operates under different parameters while supplying power. SoH data is collected and analyzed to identify the most favorable operating conditions. The SoH data may be obtained after a test and analyzed based on factors such as depth of discharge, state of charge, temperature, charge/discharge rates, and total power output over time. Battery subsets may be grouped based on identical battery characteristics and power conversion hardware. The SoH data reflects each subset's current capacity compared to its original capacity, providing insights into health, performance, and longevity.

### FIELD OF THE DISCLOSURE

The present invention generally relates to the field of managing a power grid, and more particularly to managing battery energy storage systems (BESS).

### BACKGROUND

Electric utilities that rely on battery energy storage systems (BESS) face numerous challenges when it comes to accurately assessing the state of health (SoH) of their battery systems. While SoH testing is critical for ensuring optimal performance and longevity, the complex and variable operational conditions of large-scale BESS, such as different dispatch profiles, charging rates, and operating temperatures, can accelerate degradation in ways that are difficult to predict.

There are significant economic incentives to closely monitor the available capacity of a battery energy storage system (BESS) in operation. As battery capacity degrades over time, it can lead to contractual capacity shortfalls, resulting in financial penalties. To mitigate these financial penalties, BESS sites often incorporate additional batteries and sometimes inverters to compensate for the inevitable degradation. It is crucial to determine the sizing and timing of these augmentations before the site reaches its contractual capacity limits, ensuring that the procurement, engineering, installation, and commissioning of new assets are completed efficiently and without incurring financial repercussions.

Current methods for measuring capacity in battery energy storage systems (BESS) are often costly and can produce significantly variable results. Full site capacity tests involve charging and discharging the entire system from empty to full and back to empty while meticulously monitoring energy flows, which can lead to substantial revenue losses and are typically conducted infrequently. While Battery Management Systems (BMS) calculate a SOH value for each bank of batteries, these values are frequently unreliable due to measurement system noise, resulting in inaccurate assessments of battery performance and capacity.

Manufacturers typically develop models based on a small number of units under accelerated testing in controlled environments, but these models often do not reflect real-world conditions, leaving utilities with unreliable projections of battery life. Periodic SoH testing, which is often conducted annually to comply with Power Purchase Agreement (PPA) or warranty requirements, can temporarily remove a BESS from market participation, reducing revenue for the utility.

Moreover, the mismatch between preferred degradation testing protocols and PPA requirements can lead to errors, further complicating accurate SoH assessments. Laboratory-based SoH testing, while more controlled, may not replicate the environmental conditions BESS faces in the field, and mathematical models used to predict degradation can be inaccurate for certain battery chemistries and newer technologies.

### SUMMARY OF THE INVENTION

A system and a method is provided for determining operating parameters that improve the state of health (SoH) of a battery energy storage system (BESS). The method includes accessing the amount of electric power required over a specified period to meet a contractual obligation. The set of batteries within the BESS is then divided into multiple subsets. Each subset receives a distinct set of operating parameters while still supplying the required electric power to fulfill the contractual obligation. SoH data is collected from each subset during operation. An improved set of operating parameters is identified, providing improved SOH for the BESS based on analysis of the SOH data from each of the plurality of subsets of batteries. The BESS is instructed to operate at the improved set of operating parameters.

In one aspect, the SoH data is received in response to a SoH test is completed on the subsets of batteries. The data may further be analyzed based on the distinct set of operating parameters associated with each subset prior to the SoH test, such as depth of discharge, average state of charge, operating temperature, charge and discharge rates, total power output over a configurable period, or a combination thereof.

The division of batteries into subsets may be based on ensuring that each subset consists of identical batteries and that the power conversion hardware used for each subset is also identical. The SoH data includes information about a current capacity of each subset relative to its original capacity, providing insights into its overall health, performance, and longevity.

### BRIEF DESCRIPTION OF THE DRAWINGS

The accompanying figures where like reference numerals refer to identical or functionally similar elements throughout the separate views, and which together with the detailed description below are incorporated in and form part of the specification, serve to further illustrate various embodiments and to explain various principles and advantages all in accordance with the present disclosure, in which:

FIG. 1 is a graph of BESS (Battery Energy Storage System) measured capacity deviation from a proforma projection, according to the prior art;

FIG. 2 is a graph of BESS preferred capacity test dispatch versus a typical dispatch, according to the prior art;

FIG. 3 depicts the major electrical components of a distributed power grid with BESS, according to the prior art;

FIG. 4 depicts the major electrical components of a BESS, according to the prior art;

FIG. 5 depicts the major components for providing operating parameters for an improved state of health (SoH) of a BESS, according to the prior art;

FIG. 6 is a graph of a probability distribution function of 16 racks as part of a BESS, according to one aspect of the present invention;

FIG. 7 is a graph of a capacity test dashboard, according to one aspect of the present invention;

FIG. 8 is a graph of a comparison of expected capacity models, according to one aspect of the present invention;

FIG. 9 is a graph of a comparison of a battery degradation regression model, according to one aspect of the present invention;

FIG. 10 depicts the control logic, data collection, analysis tools, and forecasting models to adjust the operating parameters of BESS, according to one aspect of the present invention;

FIG. 11 is a flow diagram for improving operating parameters, according to one aspect of the present invention; and

FIG. 12 illustrates a block diagram illustrating a processing system for carrying out portions of the present invention, according to an example.

### DETAILED DESCRIPTION

As required, detailed embodiments are disclosed herein; however, it is to be understood that the disclosed embodiments are merely examples and that the systems and methods described below are embodied in various forms. Therefore, specific structural and functional details disclosed herein are not to be interpreted as limiting but merely as a basis for the claims and as a representative basis for teaching one skilled in the art to variously employ the disclosed subject matter in virtually any appropriately detailed structure and function. Further, the terms and phrases used herein are not intended to be limiting but rather to provide an understandable description.

### Non-limiting Definitions

Generally, the terms “a” or “an”, as used herein, are defined as one or more than one. The term plurality, as used herein, is defined as two or more than two.

The term “adapted to” describes the hardware, software, or a combination of hardware and software that is capable of, able to accommodate, to make, or that is suitable to carry out a given function.

The term “another”, as used herein, is defined as at least a second or more.

The term “battery” means any electrochemical device that provides electric power, including lead-acid batteries, alkaline, nickel oxyhydroxide, zinc-air, silver-oxide, magnesium, lithium-ion batteries, or one or more combinations of battery technologies.

The term “battery energy storage systems” or BESS are rechargeable battery systems that store energy from energy generating sources, like wind and solar power, or the electric grid, and provide that energy back to the electric grid and then to a home or business. BESS often has controllers and algorithms to coordinate energy production, and computerized control systems are used to decide when to keep the energy to provide reserves or release it to the grid. BESS can efficiently perform certain tasks that used to be difficult or impossible, such as peak shaving and load shifting.

The term “battery management system (BMS)” is an electronic system designed to manage and protect the performance and safety of rechargeable batteries, commonly used in electric vehicles, energy storage systems, and portable electronics. It monitors key battery parameters such as voltage, current, temperature, and the state of charge (SOC) to ensure optimal operation. In multi-cell batteries, the BMS balances the charge among cells, preventing uneven wear and extending the battery's lifespan. It also provides essential protection by preventing overcharging, over-discharging, overheating, and short circuits, cutting off the battery if any unsafe conditions arise. Additionally, the BMS calculates the battery's state of health (SoH), indicating how much the battery has degraded over time, and tracks the SoC to determine the remaining charge. Often, the BMS communicates with external systems, such as a vehicle's power management system or an energy grid, to deliver real-time information on battery status and performance. Overall, the BMS is essential for ensuring the safety, efficiency, and longevity of batteries.

The term “contractual obligation,” also known in the industry as a “power purchase agreement (PPA),” is a financial arrangement where a buyer pays a supplier an agreed rate, often fixed, for electricity generated over a set period of time. The supplier is responsible for developing, building, and maintaining the renewable energy system. Another contractual obligation is to bid to supply power and then supply power in response to current market prices.

The term “configured to” describes hardware, software or a combination of hardware and software that is adapted to, set up, arranged, built, composed, constructed, designed, or that has any combination of these characteristics to carry out a given function.

The term “coupled,” as used herein, is defined as “connected,” although not necessarily directly, and not necessarily mechanically.

The term “demand charges” means the highest level of electricity demand during a billing period (“peak demand”) and are measured in kilowatts (kW). Demand charges are not typically charged to residential customers. Commercial and industrial electricity customers are typically billed for energy in two distinct ways: consumption charges and demand charges. Demand charges can be as much as fifty percent of the total electric bill or more. Demand charges apply when X kilowatt peak demand load is recorded for more than Y minutes during the defined demand charge times, where the power provider sets X and Y.

The phrase “electrical distribution layout” in the electric energy center is one or more electrical devices that distribute electricity, for example, any combination of breakers, feeders, and load centers.

The terms “including” and “having,” as used herein, are defined as comprising (i.e., open language).

The term “ON” in relation to a cooling system means the cooling system is energized to cool a BESS, whereas the term “OFF” in relation to a cooling system means the cooling system is not energized to cool the BESS.

The term “or” is intended to mean an inclusive “or” rather than an exclusive “or.” That is, unless specified otherwise or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

The term “power conversion hardware” generally refers to DC-DC converters and DC to AC inverters, and other hardware used to provide AC power at a specific frequency, voltage level, and current to the power grid.

The term “state of health (SoH)” refers to a battery's condition, indicating how much it has degraded and how much capacity remains. SoH is expressed as a percentage, comparing the battery's maximum charge to its original rated capacity. This metric is crucial for assessing the battery's performance, longevity, and safety, allowing for predictive maintenance, warranty management, and extending its life. SoH is calculated by comparing the remaining capacity to the initial capacity, and it decreases over time with charge-discharge cycles. A battery management system (BMS) continuously monitors SoH and the state of charge (SoC) by measuring voltage, current, and temperature to ensure optimal operation.

Unless explicitly stated otherwise, each numerical value and range should be interpreted as being approximate as if the word “about” or “approximately” preceded the value of the value or range.

It should be understood that the steps of the methods set forth herein are not necessarily required to be performed in the order described, and the order of the steps of such methods should be understood to be merely exemplary. Likewise, additional steps may be included in such methods, and certain steps may be omitted or combined in methods consistent with various embodiments of the present device.

Although the elements in the following method claims, if any, are recited in a particular sequence with corresponding labeling unless the claim recitations otherwise imply a particular sequence for implementing some or all of those elements, those elements are not necessarily intended to be limited to being implemented in that particular sequence.

### Overview

One aspect of the present invention is to provide more adaptive and real-time SoH monitoring methods to address the limitations of infrequent or inaccurate testing, which can leave utilities vulnerable to unexpected failures, operational inefficiencies, and financial losses.

More specifically, the claimed invention provide a data collection system that is integrated into the control of a BESS facility. The site is controlled by a device known as an Energy Management System (EMS) that takes instructions from an outside scheduling entity and assigns commands to individual components inside the BESS. The invention modifies the typical process of evenly distributing power commands across all lineups in a BESS facility. Rather than equal or proportional instructions, the facility would be divided into test groups as defined by a test control algorithm. These test groups would be configured to run different scenarios for all the known relevant operating parameters in a consistent basis. The limits of how divergent the groups are from one another will depend on the available over-build of the facility to continue to meet contractual dispatch requirements. An additional process measures the degradation impacts to the different test populations. An analytical model integrates the various tested values and test cases to determine the relative degradation impacts of different operating parameters via machine learning.

The claimed invention improves on available test methods using laboratory testing but evaluating field-deployed equipment. This will include the practical effects of installation locations, climate, installation practices, and details on operations impacts. By knowing the costliest operating mode, the claimed invention improves the operational efficiency of a BESS.

Aspects of the claim invention provide optimal total cost performance depending on correctly estimating site capacity values with sufficient lead time to adjust augmentation planning.

### Examples of Improvements over Prior Art

This approach enhances the quality and quantity of testing data for in-service BESS facilities without requiring dedicated test equipment or pulling field devices for lab analysis. The dataset generated is more extensive than what is typically available to original equipment vendors or other operators due to the extensive size of a utility-scale BESS installation on which this invention can be deployed.

Successful deployment of this method would enable more informed strategic decisions regarding the timing and sizing of augmentations, leading to significant savings in capital costs and preventing revenue losses from early underperformance. Measured variability in capacity loss from expectations can drive meaningful shifts in augmentation timing and sizing. Higher certainty on capacity values in the future allows for better optimization of execution resources and smoother O&M (Operations and Maintenance) impacts.

### State of Health (SoH) Lab Projections and Modeling

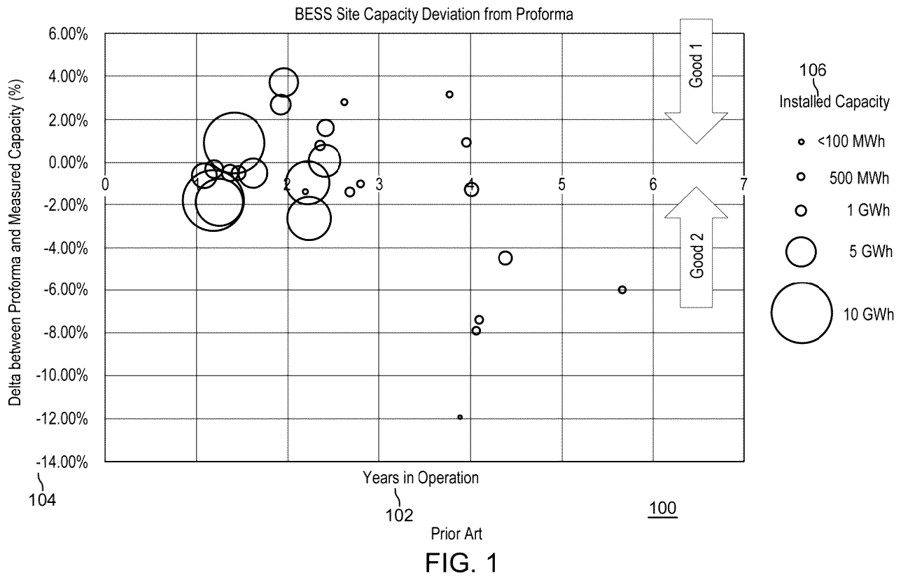

Projections from pre-construction often differ significantly from actual testing values for site capacity, introducing financial risks due to inaccurate forecasting. FIG. 1 is a graph 100 of a BESS site measured capacity deviation from a proforma projection. The X-axis 102 is the number of years that the BESS has been in operation. The Y-axis 104 is the delta as a percentage between the proforma projections and the measured capacity. The installed capacity 106 is denoted by the size of the circle. As shown, in some of the smaller capacities, e.g., less than 1 GWh, the measured BESS capacity can deviate by 8% of the proforma projection.

The financial risks can manifest as errors in two ways. The first type of financial risk error is when capacity projections are too conservative, leading to overspending on augmentation, either by increasing the size of the project or advancing its in-service date unnecessarily. Conversely, the second type of financial risk error is when projections are too aggressive, resulting in missed dispatch performance or a shortfall during capacity tests, potentially affecting operational efficiency and profitability.

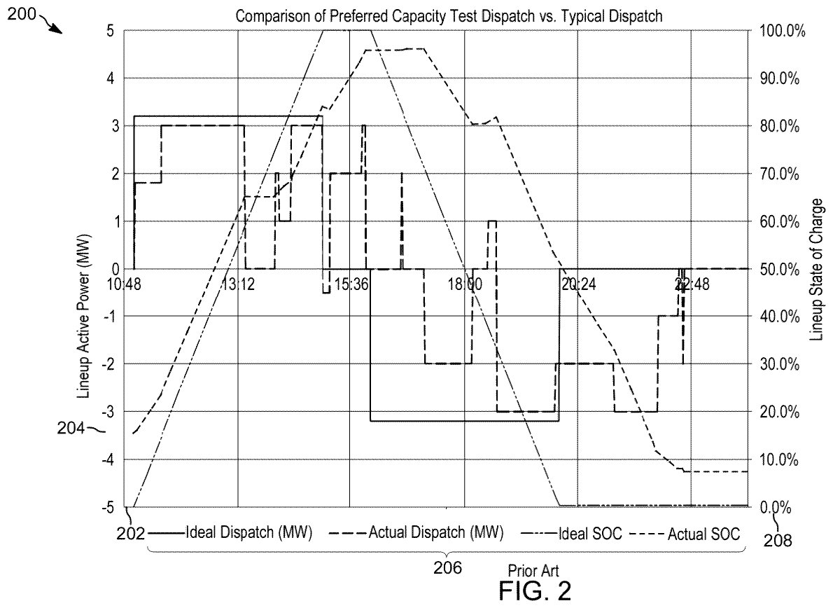

FIG. 2 is a graph 200 of BESS preferred capacity test dispatch versus a typical dispatch. The X-axis 202 is time in hours. The left Y-axis 204 is the lineup active power in MW. The right Y-axis 208 is the lineup state of charge as a percentage. Line styles 206 represent the Ideal Dispatch (MW), Actual Dispatch (MW), Ideal SOC, and Actual SOC.

Most BESS sites operate under pricing-driven dispatch schedules that fluctuate based on market conditions, resulting in dispatch patterns that do not directly measure system capacity. A comparison of typical power flow and optimal test output highlights this issue. Operating data alone is insufficient because most dispatches do not reach both the minimum and maximum states of charge for most system lineups. Even when a full depth of discharge occurs, the power flow often does not reach the system's rated power, making it challenging to accurately assess capacity based solely on operational data. As shown in FIG. 2, the ideal dispatch and the actual dispatch can vary significantly. Also, actual SOC may vary from ideal SOC by not reaching full discharge or full charge conditions.

### Battery Energy Storage System

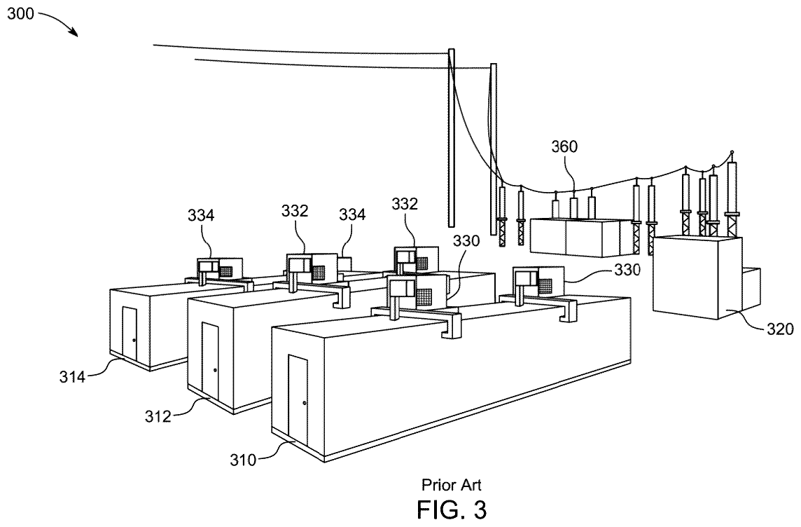

FIG. 3 depicts the major electrical components of a distributed power grid with BESS 300 as part of a renewable energy installation. This electric energy system has various electrical components, including lines, switch units, busbars, transformers, isolators, reactors, and other electrical components. More specifically, generally shown are BESS 310, 312, 314 with associated heating and cooling systems 330, 332, 334. BESS 310, 312, 314, in this example, are packaged in a form factor of an intermodal container or shipping container, such as a standard shipping container. Since shipping containers are designed for intermodal freight transport, these containers can be moved easily between ship, rail, and truck. Each BESS 310, 312, 314 is typically electrically coupled to a power conversion system (PCS) 320. The PCS is a bi-directional inverter with harmonic filters for converting DC voltage from each BESS 310, 312, 314 to AC voltage to be compatible with the power grid 360.

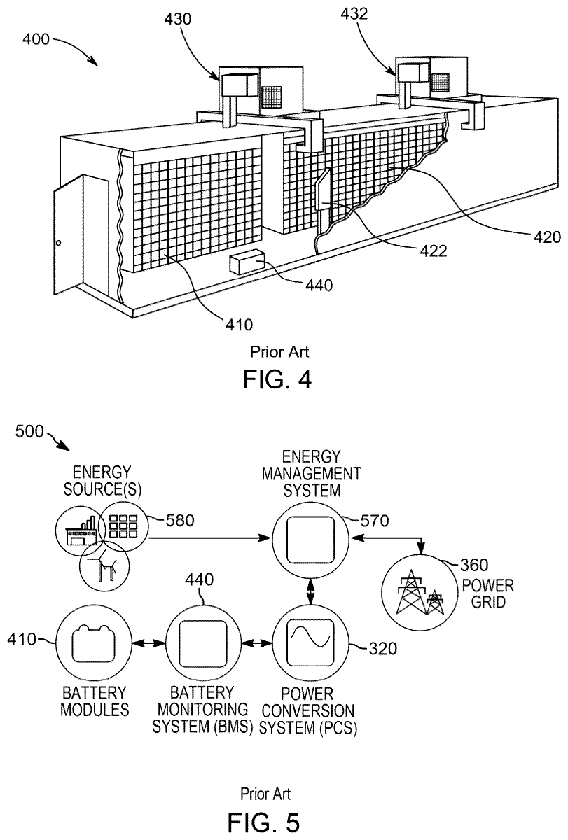

FIG. 4 depicts an example of the major electrical components 400 of a BESS, such as BESS 310, 312, 314 of FIG. 3. Arrays 410, 420 of battery modules 422 are arranged as shown. Each battery module is typically made up of a group of battery cells (not shown). The battery modules 422 may use any battery technology known or developed in the future. Battery modules 422 that are dead or malfunctioning may be replaced within the arrays 410, 420. Also shown is a battery monitoring system (BMS) 440. The BMS 440 is a local control for the charging and discharging of battery modules 422. The BMS 440 may also control other systems, such as the heating and cooling systems 430, 432.

### BESS Operating Parameter Controls

FIG. 5 depicts the major components 500 for providing operating parameters for an improved state of health (SoH) of the BESS 310, 312, 314 from FIG. 3. Various energy sources 580, including conventional energy sources, natural gas, coal, and nuclear, plus renewable energy sources such as wind and solar, are shown. The power is delivered to power grid 360 from the various energy sources 580. The energy management system 570 controls how much power is delivered from the various energy sources 580 to the power grid 360 and from BESS 310, 312, 314 to the grid. There are three major operating modes of the energy management system 570. The first operating mode of the energy management system 570 sends one hundred percent of the power from the various energy sources 580. The second operating mode of the energy management system 570 sends a hundred percent of the power from the battery modules 422 of an array 420 through the BMS 440 and PCS 320. The third operating mode of the energy management system 570 sends a combination of power from both the various energy sources 580 and the array 420.

### Analysis Used To Improve Operating Parameters

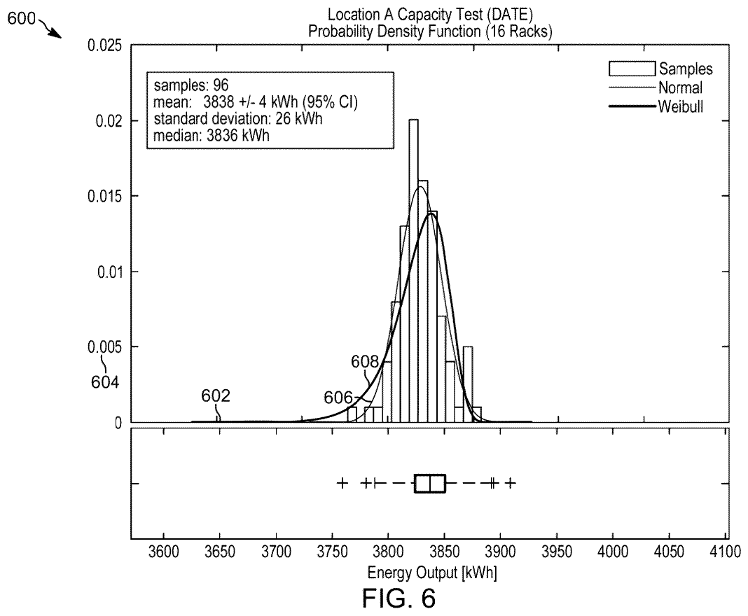

FIG. 6 is a graph 600 of a probability distribution function of 16 racks as part of a BESS. Shown are 96 samples, with a mean of 3838+/−4 KWh (95% confidence interval (CI). The standard deviation is 26 kWh, and the median is 3836 kWh. The X-axis 602 is the energy output of the BESS in KWh. This is a measured energy capacity per lineup. Data is displayed in a histogram that bins test results between defined values and increases the height of the bar at that point to show the relative frequency of test results occurring within the specified range. The Y-axis 604 is different energy capacity measurements for subsections of a BESS. Line 606 represents a normal or Gaussian probability distribution of the samples. Line 608 is a Weibull distribution or a continuous probability distribution of the samples.

Referring to graph 600, the CI must be defined, and precision must optimize the level of certainty in forecast and execution costs for additional testing. More specifically, the CI around the sample mean estimates the range within which the population mean is likely to fall. The CI is determined using the uncertainty observed during the capacity test and a specified level of precision. Uncertainty provides a measure of the standard error, which is calculated based on the number of battery banks tested and the standard deviation of the energy dataset. It is important to note that uncertainties arising from related instruments, the data acquisition system, or the data historian are not included in these calculations. The desired precision is typically defined by business or engineering requirements.

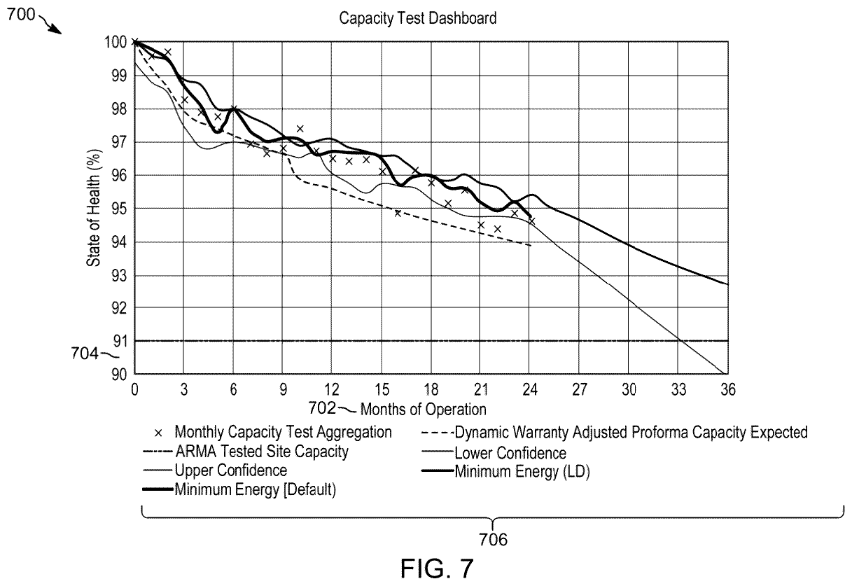

FIG. 7 is a graph 700 of a capacity test dashboard. The X-axis 702 is the months of operation of a BESS. The Y-axis 704 is the state of health (SoH) in a percentage. As described in legend 706, the seven line styles represent the monthly capacity test aggregation, statistical model, upper confidence, minimum energy, dynamic warranty adjusted for proforma capacity expected, lower condition, and minimum energy. In this example, the statistical module used is ARMA (Auto-Regressive Moving Average) to estimate current trends in output. It can be used as a basis for projecting into the future, but other statistical models may be used.

In this example, the graph 700 is a shared visualization platform of capacity status across the organization. This platform may be designed to evaluate and display testing results, expected values, and projections in a clear and actionable manner. Key objectives include integrating data from testing, expected performance values, and projection models while displaying relevant results alongside planned augmentation projects. Additionally, the platform should visualize upper and lower confidence bounds for projections and flag a BESS that is at risk of underperformance.

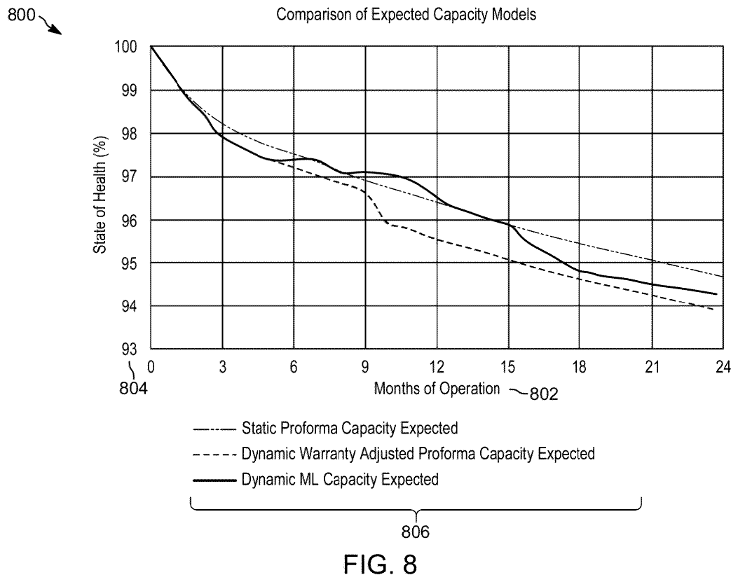

FIG. 8 is a graph 800 of a comparison of expected capacity models. The X-axis 802 is the number of months of operation. The Y-axis 804 is the SoH in a percentage of the BESS. Line style represents each of the static proforma capacity expected, dynamic warranty adjusted proforma capacity expected, and dynamic Machine Learning or other mathematical models of expected capacity are described in legend 806.

One possible approach for visualizing dispatch profiles is to incorporate multiple expected capacity models. Expected degradation projections help identify capacity loss over time, while a static expected capacity model provides a benchmark for comparing actual performance against project approval expectations. A dynamic, warranty-adjusted model reflects the guaranteed capacity-based on-site operations, adjusting downward when warranty limits are exceeded but without the ability to recover that lost gap over time. Additionally, a machine learning-driven dynamic model refines expectations by analyzing all available operating data, selecting weighting factors based on comparisons with similar equipment under different operating conditions. This adaptive approach allows capacity expectations to be adjusted up or down depending on actual usage patterns.

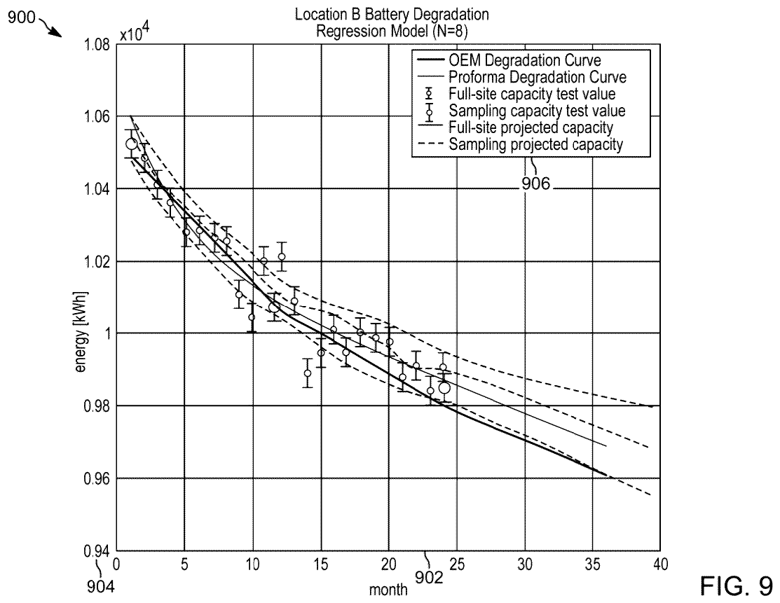

FIG. 9 is a graph 900 of a comparison of a battery degradation regression model. The X-axis 902 is the number of months of operation. The Y-axis 904 is the energy kWh. Line styles are described in legend 906.

Advancing capacity testing capabilities for operating assets is important for accurately projecting augmentation needs and timing. Traditional annual capacity testing does not provide sufficient data to predict capacity losses leading up to the next augmentation, making it necessary to refine testing methods. A key consideration is the balance between sampling and site-wide degradation testing, particularly as changes in degradation rates are more relevant for emerging battery chemistries. By leveraging site over-build capacity, the impact on Asset Life Ratio (ALR) remains minimal. This approach is expected to improve forecasting confidence regarding capacity shortfalls, enabling more precise adjustments to augmentation timing.

### Control Logic, Data Collection, Analysis Tools and Forecasting Models

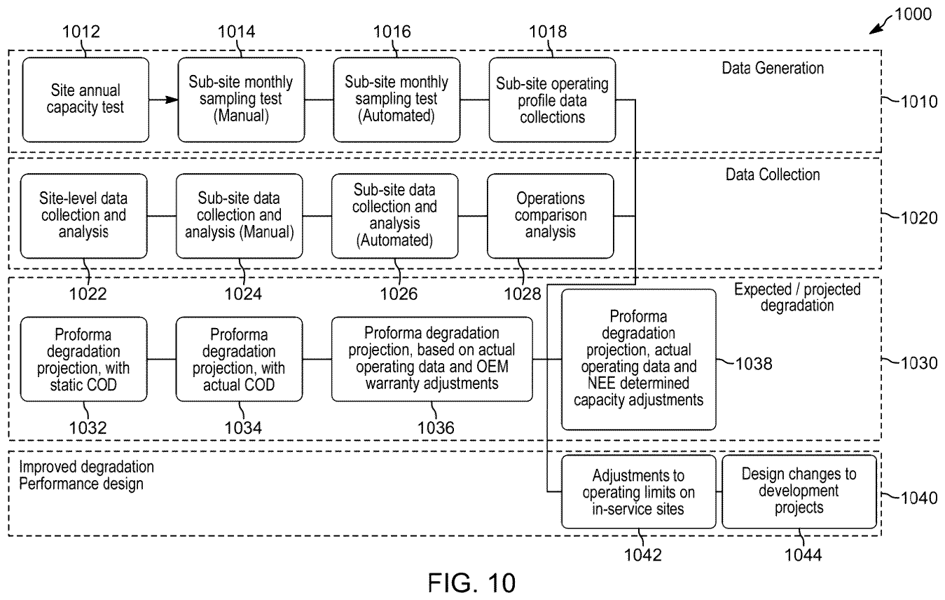

FIG. 10 depicts a capacity and augmentation projection flow 1000 of the control logic, data collection, analysis tools, and forecasting models to adjust the operating parameters of BESS. Developing site control logic, data collection and analysis tools, and forecasting models are used for improving cost projection capabilities. The capacity and augmentation projection flow 1000 includes an initial phase of manual sampling testing at 10 sites. However, conducting these tests and processing the associated data is time-intensive, necessitating automation for scalability. The development of accurate capacity projection models relies on collecting sufficient data to establish reliable trends. Once deployed, capacity monitoring tools will enable tracking the impacts of different operating profiles at in-service facilities, providing valuable insights for optimizing performance and planning future augmentations.

The capacity and augmentation projection flow 1000 is separated into four major areas: 1) data generation 1010, 2) data collection 1020, 3) expected projected degradation 1030, and 4) improved degradation and performance design 1040.

The capacity and augmentation projection flow 1000 begins with data generation 1010, where data is obtained from various sources. This data may come from computational models, real-world measurements, or historical records. For example, battery performance can be simulated under different conditions, i.e., real-time operational metrics from the BESS can be measured from site annual capacity test 1012, sub-site monthly sampling test (manual) 1014, sub-site monthly sampling test (automated) 1016, and sub-site monthly operating profile data collections 1018.

Once data is generated, the next step is data collection 1020, which involves systematically gathering, organizing, and verifying information. Data may be aggregated data from sensors, structuring it into databases, filtering out incomplete or redundant data, and ensuring its accuracy and consistency. Proper data collection ensures that the subsequent analysis is based on reliable information, reducing errors and biases in projections. This data collection may include site-level data collection and analysis 1022, sub-site data collection and analysis (manual) 1024, sub-site data collection and analysis (automatic) 1026, and operation comparison analysis 1028.

Using the collected data from data collection 1020, analysts then assess expected or projected degradation 1030, estimating how system performance will decline over time. Degradation can refer to the loss of battery capacity due to repeated charge/discharge cycles and decreased efficiency of energy storage systems. Predictive models help forecast these trends, providing insights into when maintenance, upgrades, or replacements might be needed. Degradation models include proforma degradation projection with static COD (Commercial Operation Date) 1032, proforma degradation projection with actual COD 1034, proforma degradation projection based on actual operating data and OEM warranty adjustments 1036, and proforma degradation projection, actual operating data, and determined capacity adjustments 1038. Degradation models assume a fixed COD, but conditions arise when project completion shifts, requiring changes to proforma expectations for augmentation timing.

Following this, Improved Degradation and Performance Design 1040 is performed. These design strategies include adjustments to operating limits on in-service sites 1042 and design changes to development projects 1044. The design strategies are implemented to achieve improved degradation, which focuses on mitigating these performance losses and extending the system lifespan. The timing of these augmentations can be during any time frame, including daily, weekly, monthly, quarterly, etc. Design strategies can involve optimizing battery management strategies, improving cooling systems to reduce thermal stress, modifying operational parameters for efficiency, assigning more/less aggressive dispatch commands to portions of the system, shifting operating voltage ranges, modifying battery current limits, adjusting limits for resting state of charge or using advanced materials to slow degradation. By refining degradation models and implementing targeted improvements, the overall performance design is optimized, ensuring long-lasting and reliable energy storage solutions.

### Controlling Batteries in BESS to Improve Operating Parameters

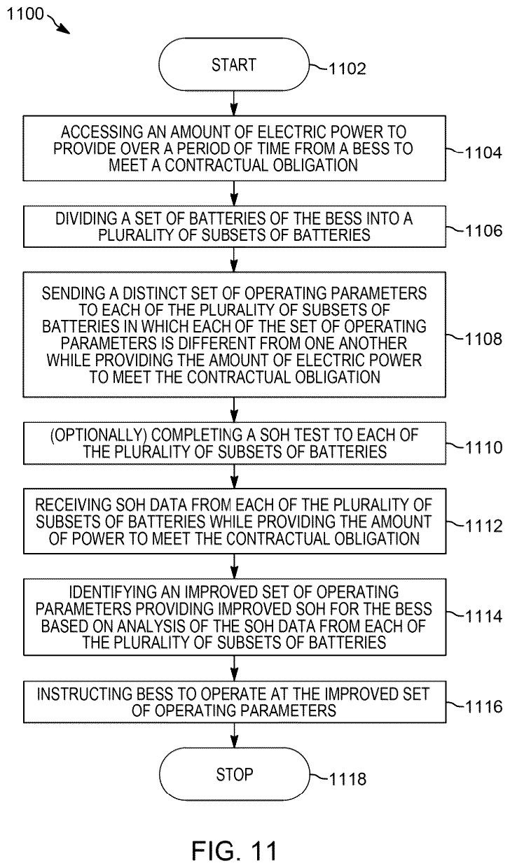

FIG. 11 is a flow diagram 1100 for improving operating parameters. The process starts at step 1102 and immediately proceeds to step 1104. In step 1104, an amount of electric power to be provided over a period of time from a BESS is accessed to meet a contractual obligation. The process continues to step 1106.

In step 1106, a set of batteries is divided into a plurality of subsets of batteries of the BESS. The subsets may be configured to have identical characteristics to ensure that each of the plurality of subsets of batteries is as similar or identical as possible. For example, the subsets may include batteries of the same manufacturer, capacity, and power conversion hardware (e.g., make and model number associated with providing electrical power from each subset). The process continues to step 1108.

In step 1108, a distinct set of operating parameters is sent to each of the plurality of subsets of batteries. These distinct set of operating parameters specify the amount of electric power required to meet the contractual obligation. Examples of such operating parameters include a depth of discharge, an average state of charge, operating temperature, a rate of charge, a rate of discharging, a total amount of power provided over a settable period, or a combination thereof. The process continues to step 1110.

Step 1110 is an optional step. A SoH test is sent to each of the plurality of subsets of batteries, and the SoH is completed prior to receiving the SoH data in step 1112. The process continues to step 1112.

In step 1112, SoH data is received from each of the subsets of batteries while proving the amount of power to meet the contractual obligation. The SoH data may include the current capacity of the subset of batteries related to their overall health, performance, and longevity compared to the original capacity of the subsets of batteries. Further, the SoH data can include parameters of each of the subsets of batteries prior to the SoH test. The parameters include one or more of a depth of discharge, an average state of charge, an operating temperature, a rate of charge, a rate of discharging, a total amount of power provided over a settable period of time, or a combination thereof. The process continues to step 1114.

In step 1114, the SoH data is analyzed from each of the subsets of batteries to identify the set of operating parameters providing improved SoH for the BESS. In one example, SoH may be measured by assessing the subset of batteries'ability to store and deliver energy compared to their original specifications. There are several methods to evaluate SoH, including any combination of:
i) Capacity Testing—Measure the actual capacity of the battery (Ah or Wh) by fully charging and discharging it and compare the measured capacity to the nominal capacity.
ii) Internal Resistance Measurement—Higher internal resistance often indicates aging or degradation, and electrochemical impedance spectroscopy (EIS) or a simple DC resistance test is used.
iii) Voltage Analysis—Monitor the voltage response under load. Significant voltage drops may indicate reduced health.
iv) Coulomb Counting—Track the total charge input and output over time, which helps identify capacity loss.
v) Self-discharge rate—Measure how quickly the battery loses charge when not in use. Increased self-discharge rates are a sign of aging.
vi) Cycle Counting—Track the number of charge/discharge cycles. Compare against the expected cycle life of the battery.
vii) Temperature Monitoring—Increased heat generation during use or charging may signal internal issues.
viii) Model-Based Estimation—Use algorithms and models (e.g., Kalman filters) to estimate SoH based on current, voltage, and temperature data.
ix) Round-trip efficiency comparisons against baseline.
x) Proprietary SoH calculation provided by Original Equipment Manufacturer of Battery management systems.

### The Process Continues to Step 1116.

In step 1116, the BESS is instructed to operate at the improved set of operating parameters from step 1114. The process continues to step 1118.

The process continues to step 1118, where the process ends.

### General Computer for Implementing Algorithm

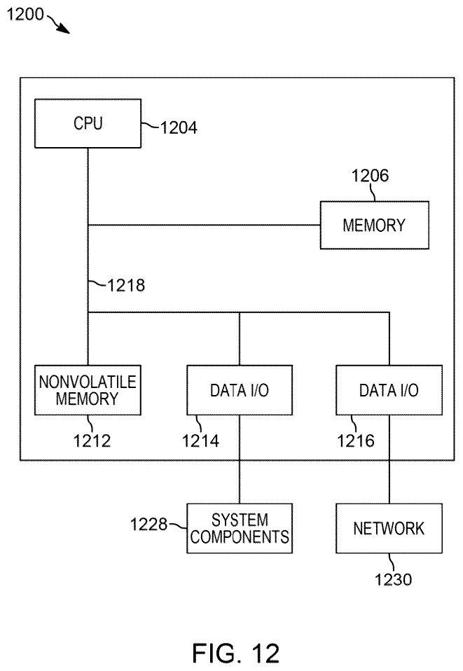

FIG. 12 illustrates a block diagram illustrating a processing system 1200 for carrying out a portion of the present invention, according to an example. The processing system 1200 is an example of a processing subsystem that is able to perform any of the above-described processing operations, control operations, other operations, or combinations of these, such as the energy management system 570 and the battery monitoring system (BMS) 440.

The processing system 1200 in this example includes a hardware processor or CPU 1204 that is communicatively connected to a main memory 1206 (e.g., volatile memory), a non-volatile memory 1212 to support processing machine instruction and operations. The CPU is further communicatively coupled to a network adapter hardware 1216 to support input and output communications with external computing systems such as through the illustrated network 1230.

The processing system 1200 further includes a data input/output (I/O) processor 1214 that is able to be adapted to communicate with any type of equipment, such as the illustrated system components 1228. The data input/output (I/O) processor, in various examples, is able to be configured to support any type of data communications connections, including present-day analog and/or digital techniques or via a future communications mechanism. A system bus 1218 interconnects these system components.

### Information Processing System

The present subject matter can be realized in hardware, software, or a combination of hardware and software. A system can be realized in a centralized fashion in one computer system or in a distributed fashion where different elements are spread across several interconnected computer systems. Any kind of computer system- or other apparatus adapted for carrying out the methods described herein—is suitable. A typical combination of hardware and software could be a general-purpose computer system with a computer program that, when being loaded and executed, controls the computer system such that it carries out the methods described herein.

The present subject matter can also be embedded in a computer program product, which comprises all the features enabling the implementation of the methods described herein, and which—when loaded in a computer system—is able to carry out these methods. Computer program in the present context means any expression, in any language, code, or notation, of a set of instructions intended to cause a system having an information processing capability to perform a particular function either directly or after either or both of the following a) conversion to another language, code or, notation; and b) reproduction in a different material form.

Each computer system may include, inter alia, one or more computers and at least a computer readable medium allowing a computer to read data, instructions, messages or message packets, and other computer readable information from the computer readable medium. The computer readable medium may include computer readable storage medium embodying non-volatile memory, such as read-only memory (ROM), flash memory, disk drive memory, CD-ROM, and other permanent storage. Additionally, a computer medium may include volatile storage such as RAM, buffers, cache memory, and network circuits. Furthermore, the computer readable medium may comprise computer readable information in a transitory state medium such as a network link and/or a network interface, including a wired network or a wireless network, that allow a computer to read such computer readable information. In general, the computer readable medium embodies a computer program product as a computer readable storage medium that embodies computer readable program code with instructions to control a machine to perform the above described methods and realize the above described systems.

### Non-Limiting Examples

Although specific embodiments of the subject matter have been disclosed, those having ordinary skill in the art will understand that changes are made to the specific embodiments without departing from the spirit and scope of the disclosed subject matter. The scope of the disclosure is not to be restricted, therefore, to the specific embodiments, and it is intended that the appended claims cover any and all such applications, modifications, and embodiments within the scope of the present disclosure.

What is claimed is:

1. A method for providing operating parameters for improved state of health (SoH) of a battery energy storage system (BESS), the method comprising:
accessing an amount of electric power to provide over a period of time from a BESS to meet a contractual obligation;
dividing a set of batteries of the BESS into a plurality of subsets of batteries;
sending a distinct set of operating parameters to each of the plurality of subsets of batteries in which each of the set of operating parameters is different from one another while providing the amount of electric power to meet the contractual obligation;
receiving SoH data from each of the plurality of subsets of batteries while providing the amount of power to meet the contractual obligation;
identifying an improved set of operating parameters providing improved SOH for the BESS based on analysis of the SOH data from each of the plurality of subsets of batteries; and
instructing BESS to operate at the improved set of operating parameters.

2. The method of claim 1, wherein the receiving the SoH data from each of the plurality of subsets of batteries is after a SoH test is completed on each of the plurality of subsets of batteries.

3. The method of claim 2, wherein the SoH data from each of the plurality of subsets of batteries is further analyzed based on the distinct set of operating parameters of each of the plurality of subsets of batteries prior to the SoH test, the distinct set of parameters being one of
a depth of discharge,
an average state of charge,
an operating temperature,
a rate of charge,
a rate of discharging,
a total amount of power provided over a settable period of time, or
a combination thereof.

4. The method of claim 1, wherein the dividing the set of batteries into the plurality of subsets of batteries is based on each battery in the subsets of batteries being identical to each other and power conversion hardware associated with providing electrical power from each subset of batteries is identical to each other.

5. The method of claim 1, wherein the SoH data from each of the plurality of subsets of batteries includes a current capacity related to overall health, performance, and longevity as compared to an original capacity of the subsets of batteries.

6. The method of claim 1, wherein the receiving the SoH data from each of the plurality of subsets of batteries while providing the amount of power to meet the contractual obligation, further includes sending a test command to a subset of batteries for measuring the SoH, while other batteries not in the subset of batteries in the BESS are providing the amount of power to meet the contractual obligation; and
in response to the test command, receiving, from the subset of batteries, respective SoH data, while other batteries not in the subset of batteries in the BESS are providing the amount of power to meet the contractual obligation.

7. The method of claim 6, further comprising:
sending to the other batteries not in the subset of batteries in the BESS instructions to maintain providing the amount of power to meet the contractual obligation while the subset of batteries are under test.

8. The method of claim 6, wherein the sending the test command to the subset of batteries includes a set of instructions to discharge the subset of batteries to a minimum state of charge, charge at a defined power rate, sit idle for a period of time, and discharge at another defined power rate.

9. The method of claim 6, wherein the SoH data from each of the plurality of subsets of batteries is further analyzed based on one or more prior operating parameters of the subset of batteries prior to the test command being sent, the one or more prior operating parameters being one of
a depth of discharge,
an average state of charge,
an operating temperature,
a rate of charge,
a rate of discharging,
a total amount of power provided over a settable period of time, or
a combination thereof.

10. A system for providing operating parameters for improved state of health (SoH) of a battery energy storage system (BESS), the system comprising:
a computer memory capable of storing machine instructions; and
a hardware processor in communication with the computer memory, the hardware processor configured to access the computer memory to execute the machine instructions to perform
accessing an amount of electric power to provide over a period of time from a BESS to meet a contractual obligation;
dividing a set of batteries of the BESS into a plurality of subsets of batteries;
sending a distinct set of operating parameters to each of the plurality of subsets of batteries in which each of the set of operating parameters is different from one another while providing the amount of electric power to meet the contractual obligation;
receiving SoH data from each of the plurality of subsets of batteries while providing the amount of power to meet the contractual obligation;
identifying an improved set of operating parameters providing improved SOH for the BESS based on analysis of the SOH data from each of the plurality of subsets of batteries; and
instructing BESS to operate at the improved set of operating parameters.

11. The system of claim 10, wherein the receiving the SoH data from each of the plurality of subsets of batteries is after a SoH test is completed on each of the plurality of subsets of batteries.

12. The system of claim 11, wherein the SoH data from each of the plurality of subsets of batteries is further analyzed based on the distinct set of operating parameters of each of the plurality of subsets of batteries prior to the SoH test, the distinct set of parameters being one of
a depth of discharge,
an average state of charge,
an operating temperature,
a rate of charge,
a rate of discharging,
a total amount of power provided over a settable period of time, or
a combination thereof.

13. The system of claim 10, wherein the dividing the set of batteries into the plurality of subsets of batteries is based on each battery in the subsets of batteries being identical to each other and power conversion hardware associated with providing electrical power from each subset of batteries is identical to each other.

14. The system of claim 10, wherein the SoH data from each of the plurality of subsets of batteries includes a current capacity related to overall health, performance, and longevity as compared to an original capacity of the subsets of batteries.

15. The system of claim 10, wherein the receiving the SoH data from each of the plurality of subsets of batteries while providing the amount of power to meet the contractual obligation, further includes sending a test command to a subset of batteries for measuring the SoH, while other batteries not in the subset of batteries in the BESS are providing the amount of power to meet the contractual obligation; and
in response to the test command, receiving from the subset of batteries, respective SoH data, while other batteries not in the subset of batteries in the BESS are providing the amount of power to meet the contractual obligation.

16. The system of claim 15, further comprising:
sending to the other batteries not in the subset of batteries in the BESS instructions to maintain providing the amount of power to meet the contractual obligation while the subset of batteries are under test.

17. The system of claim 15, wherein the sending the test command to the subset of batteries includes a set of instructions to discharge the subset of batteries to a minimum state of charge, charge at a defined power rate, sit idle for a period of time, and discharge at another defined power rate.

18. The system of claim 15, wherein the SoH data from each of the plurality of subsets of batteries is further analyzed based on one or more prior operating parameters of the subset of batteries prior to the test command being sent, the one or more prior operating parameters being one of
a depth of discharge,
an average state of charge,
an operating temperature,
a rate of charge,
a rate of discharging,
a total amount of power provided over a settable period of time, or
a combination thereof.
